(19) United States
(12) Patent Application Publication
(10) Pub. No.: US 2026/0176742 A1
(43) Pub. Date: Jun. 25, 2026

(54) NANOGRANULAR MAGNETIC FILM, MAGNETIC CORE, AND ELECTRONIC COMPONENT

(71) Applicant: TDK CORPORATION, Tokyo (JP)

(72) Inventors: Hajime AMANO, Tokyo (JP); Akito HASEGAWA, Tokyo (JP)

(73) Assignee: TDK CORPORATION, Tokyo (JP)

(21) Appl. No.: 19/389,692

(22) Filed: Nov. 14, 2025

(30) Foreign Application Priority Data
Nov. 14, 2024 (JP) 2024-199104
Oct. 17, 2025 (JP) 2025-175853

(51) Int. Cl. C23C 14/34; H01F 41/02; H01J 37/34

(52) U.S. Cl. CPC C23C 14/3407; C23C 14/3414; H01F 41/02; H01J 37/3417

(57) ABSTRACT

A nanogranular magnetic film has a structure including a second phase and first phases dispersed in the second phase. The first phases include nanoscale metal phases containing Fe and Co. The second phase contains oxygen and nitrogen. The metal phases include one or more crystallites. The one or more crystallites have crystallite sizes with a mode of 1.5 nm or more and 6.0 nm or less based on volume.

### BACKGROUND OF THE INVENTION

The present disclosure relates to a nanogranular magnetic film, a magnetic core, and an electronic component.

### DESCRIPTION OF RELATED ART

Recent mobile devices, such as smartphones and smartwatches, have been required to have a larger display and a larger battery capacity as well as a smaller size and less weight at the same time. To achieve these inconsistent requirements, it is important that circuit boards have a smaller size. In particular, power supply circuits occupying large areas in the circuit boards, or especially inductors occupying particularly large mounting areas, have been required to have a smaller size.

To downsize the inductors, increasing the operating frequencies of the power supply circuits is particularly effective. Recent markets require inductors with a high inductance at an operating frequency not lower than 100 MHz.

To develop the above inductors, thin film inductors containing a thin film magnetic material with a high magnetic resonance frequency as a core material have been studied. However, thin films manufactured with a vacuum film deposition method (e.g., a sputtering method) generally tend to have very large internal stress or distortion. Thus, such thin films manufactured with a vacuum film deposition method have a dissipation factor tan δ that easily increases.

In a situation where a thin film magnetic material containing a Co based amorphous magnetic body (e.g., CoZrTa) is used as the thin film magnetic material, influence of eddy current loss tends to be strong because of a low specific resistance of the Co based amorphous magnetic body. Thus, the dissipation factor tan δ of the thin film magnetic material tends to increase. To have a tan δ of 0.1 or less at an operating frequency of 100 MHz, the thin film magnetic material is required to have, for example, a film thickness of 500 nm or less.

Thus, in a situation where the thin film magnetic material containing a Co based amorphous magnetic body is used as a core material of a thin film inductor with a thickness of several μm or more, an insulating film (e.g., a SiO₂ film) is required to be inserted for electrical disconnection between such thin film magnetic materials with a thickness of 500 nm or less. That is, the core material of the thin film inductor with a thickness of several μm or more is required to have a multilayer structure including at least a few dozen layers. The larger the number of layers of the core material having the multilayer structure, the larger the manufacturing costs.

Nanogranular magnetic films disclosed in Patent Documents 1 to 6 are known as thin films having both a relatively high saturation magnetic flux density and a high specific resistance. Using these nanogranular magnetic films for manufacture of the core material of the thin film inductor can reduce the number of layers, reducing manufacturing costs. Thus, a thin film inductor including a nanogranular magnetic film as a core material of the thin film inductor has been studied.

### PRIOR ART DOCUMENTS

### Patent Documents

[Patent Document 1] JP Patent Application Laid Open No. H11-77739
[Patent Document 2] JP Patent No. 3152647
[Patent Document 3] JP Patent Application Laid Open No. 2005-276367
[Patent Document 4] JP Patent No. 3809418
[Patent Document 5] JP Patent No. 3956061
[Patent Document 6] JP Patent No. 6618298

### BRIEF SUMMARY OF THE INVENTION

### Means for Solving the Problem

A nanogranular magnetic film according to the present disclosure is
a nanogranular magnetic film having a structure including
a second phase, and
first phases dispersed in the second phase,
wherein
the first phases include nanoscale metal phases containing Fe and Co,
the second phase contains oxygen and nitrogen,
the metal phases include one or more crystallites, and
the one or more crystallites have crystallite sizes with a mode of 1.5 nm or more and 6.0 nm or less based on volume.

The one or more crystallites may have crystallite sizes with a mode of 2.0 nm or more and 5.0 nm or less.

A value given by dividing a nitrogen concentration of the nanogranular magnetic film by a total of an oxygen concentration and the nitrogen concentration of the nanogranular magnetic film may be 0.090 or more and 0.50 or less based on number of atoms.

The first phases may occupy a volume fraction of 48% or more and 90% or less in total.

The first phases may occupy a volume fraction of 48% or more and 70% or less in total.

A magnetic core according to the present disclosure includes the above nanogranular magnetic film.

An electronic component according to the present disclosure includes the above nanogranular magnetic film.

### BRIEF DESCRIPTION OF THE SEVERAL VIEWS OF THE DRAWING

FIG. 1 is a schematic cross-sectional view of a nanogranular magnetic film.

FIG. 1A is a STEM bright field image of a cross section of the nanogranular magnetic film.

FIG. 1B is an enlarged image of FIG. 1A.

FIG. 1C is an enlarged image of FIG. 1B.

FIG. 2 is a schematic cross-sectional view of a manufacturing apparatus.

FIG. 3 is a schematic view of the manufacturing apparatus.

FIG. 4 is a schematic view of the manufacturing apparatus.

FIG. 5 is a schematic view of a diffraction chart.

FIG. 6 is a schematic view of a diffraction chart.

FIG. 7 is a schematic view of a diffraction chart.

### DETAILED DESCRIPTION OF THE INVENTION

It is an object of the present disclosure to provide a nanogranular magnetic film with a high saturation magnetic flux density Bs, a high real part of complex permeability under operation at a high frequency of 100 MHz, and a low tan δ.

An embodiment of the present disclosure is described below with reference to the drawing.

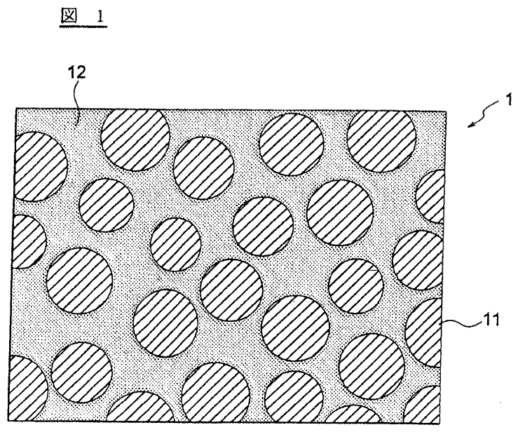

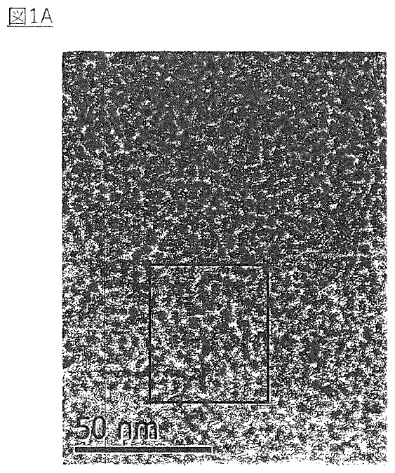

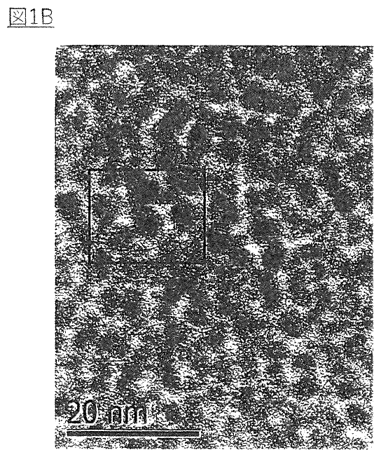

As shown in FIG. 1, a nanogranular magnetic film 1 according to the present embodiment has a structure in which first phases 11 are dispersed in a second phase 12.

FIGS. 1A to 1C are STEM bright field images. FIG. 1B is an enlarged image of a boxed part of FIG. 1A. FIG. 1C is an enlarged image of a boxed part of FIG. 1B. Black portions of each image are the first phases, which are metal phases. A white portion of each image is the second phase, which contains SiO₂ and Si₃N₄. It is discovered, through observation of the STEM images at an appropriate magnification, that the first phases have a shape close to a sphere. Moreover, it is discovered that, in the structure, the first phases are separated by the second phase.

It can be confirmed that the nanogranular magnetic film shown in FIGS. 1A to 1C has the structure shown in FIG. 1, i.e., the structure in which the first phases 11 are dispersed in the second phase 12.

It is discovered that the first phases or the metal phases have a crystal structure also from lattice images confirmable in the STEM bright field images.

The nanogranular magnetic film indicates a thin film with the above structure including the first phases 11 being the metal phases having an average size of 30 nm or less and containing a magnetic body and the second phase 12 containing a material with higher electrical resistance than that of the first phases 11 and other than resin (a material other than organic polymer compounds) as a main component. The material contained as the main component of the second phase 12 is, specifically, at least one selected from the group consisting of an oxide, a nitride, a fluoride, an oxynitride, an acid fluoride, and their mixed phase, which are inorganic substances.

Methods of confirming that the second phase 12 contains a material other than resin as the main component are not limited. Examples of such methods include a method involving XPS. Use of XPS enables the carbon content of the second phase 12 to be quantified and a bonding state of carbon in the second phase 12 to be simultaneously understood. The second phase 12 can be deemed to contain a material other than resin as the main component when the second phase 12 has a trace carbon content, i.e., the ratio of the carbon content to the total content of elements other than magnetic metal elements (e.g., Fe, Co, and Ni) and H in the second phase 12 is 20 at % or less, or when the presence of carbon bonding unique to resin is not confirmed in the second phase 12.

Methods of confirming that the second phase 12 contains a material with higher electrical resistance than that of the first phases 11 as the main component are not limited. For example, first, the composition of the first phases 11 is measured. A thin film having the same composition as that of the first phases 11 is deposited on a substrate to prepare a substrate for measuring electrical resistance of the first phases 11. Similarly to the substrate for measuring electrical resistance of the first phases 11, a substrate for measuring electrical resistance of the second phase 12 is prepared. Electrical resistances of the thin films deposited on the substrates for measuring electrical resistances are compared.

A ribbon manufactured with a liquid quenching method, a sintered body manufactured with powder sintering, and a molded body resulting from bulk cutting and molding are not nanogranular magnetic films even if they have a structure in which first phases 11 are dispersed in a second phase 12, literally.

The nanogranular magnetic film 1 includes nanoscale metal phases (metal phases with a size of 30 nm or less) containing Fe and Co as the first phases 11. The nanoscale metal phases may contain X1 besides Fe and Co. X1 may include at least one selected from the group consisting of Ni, B, C, P, V, Cr, Mn, Cu, Zn, Nb, Mo, Ru, Rh, Pd, Ag, Sn, Ta, W, Ir, Pt, and Au.

The first phases 11 of the nanogranular magnetic film 1 may have a maximum size of 30 nm or less. Methods of measuring the sizes of the first phases 11 are not limited. In the present embodiment, the sizes are found using an analysis with an FP method. A reason for using the FP method is described later. Circle equivalent diameters of the first phases 11 in a cross section of the nanogranular magnetic film 1 may be deemed to be the sizes of the first phases 11 in a situation where a cross-sectional analysis of the nanogranular magnetic film 1 using a TEM is performed.

Each metal phase includes one or more crystallites. Each metal phase may include only the one or more crystallites. Each metal phase may include an amorphous solid besides the one or more crystallites.

The first phases 11 may have a composition represented by a composition formula FeₐCo_{b}X1_{c} (in atomic ratio), where 0.30≤a≤0.90, 0.10≤b≤0.70, 0.00≤c≤0.10, and a+b+c=1 are satisfied.

The first phases 11 may contain elements besides Fe, Co, and X1. The ratio of the total content of the elements other than Fe, Co, and X1 to the total content of Fe, Co, and X1 may be 10 at % or less or may be 5 at % or less.

The second phase 12 of the nanogranular magnetic film 1 contains O and N. The second phase 12 may contain M and/or X2 besides O and N. M may include at least one selected from the group consisting of Si, Al, Ga, Mg, Zr, Hf, and a rare earth element. X2 may include at least one selected from the group consisting of F and S. The rare earth element is not limited and may be, for example, Y or La. Any of an oxide, a nitride, or an oxynitride contained in the second phase 12 may be any of an M oxide, an M nitride, or an M oxynitride. The second phase 12 may partly contain a fluoride.

The second phase 12 may have a composition represented by a composition formula M_{d}OₑN_{f}X2_{g} (in atomic ratio), where 0.10≤f/(e+f)≤0.50, 0.00≤g≤0.03, and d+e+f+g=1 are satisfied.

In a situation where the second phase 12 is represented by the composition formula M_{d}OₑN_{f}X2_{g} (in atomic ratio), the second phase 12 of the nanogranular magnetic film 1 may contain elements besides M, O, N, and X2. The ratio of the total content of the elements other than M, O, N, and X2 to the total content of M, O, N, and X2 may be 10 at % or less or may be 5 at % or less.

The second phase 12 may have a composition represented by a composition formula M_{d}OₑN_{f}X2_{g} (in atomic ratio), where M includes at least one selected from the group consisting of Si, Al, Ga, Mg, Zr, Hf, and a rare earth element, and 0.20≤d≤0.50, 0.10≤f/(e+f)≤0.50, 0.00≤g≤0.03, and d+e+f+g=1 are satisfied.

In a situation where the second phase 12 is represented by the composition formula M_{d}OₑN_{f}X2_{g} (in atomic ratio), the second phase 12 of the nanogranular magnetic film 1 may contain elements besides M, O, N, and X2. The ratio of the total content of the elements other than M, O, N, and X2 to the total content of M, O, N, and X2 may be 10 at % or less or may be 5 at % or less.

The volume fraction of the first phases 11 in the total volume of the first phases 11 and the second phase 12 is not limited. The volume fraction may be, for example, 48% or more and 90% or less, or 48% or more and 70% or less. That is, V₁/(V₁+V₂) may be 0.48 or more and 0.90 or less or may be 0.48 or more and 0.70 or less, where V₁ denotes the volume of the first phases 11 and V₂ denotes the volume of the second phase 12. The higher the volume fraction of the first phases 11 in the total volume of the first phases 11 and the second phase 12, the higher the Bs but lower the specific resistance.

Methods of analyzing the composition of the first phases 11 and the composition of the second phase 12 of the nanogranular magnetic film 1 and methods of measuring V₁/(V₁+V₂), which is the volume fraction of the first phases 11 in the total volume of the first phases 11 and the second phase 12, are not limited. They can be calculated using, for example, results of XRF measurement of the nanogranular magnetic film 1. The volume fraction may be calculated also using the area fraction of the first phases 11 in the total area of the first phases 11 and the second phase 12 through observation of a cross section of the nanogranular magnetic film 1 with a TEM. In this situation, the area fraction is converted into the volume fraction.

In a situation where the composition of the first phases 11 and the composition of the second phase 12 of the nanogranular magnetic film 1 are analyzed using XRF, low quantitative accuracy of period 1 elements and some period 2 elements, particularly O and N, is problematic. However, that O and N are relatively contained in either the first phases 11 or the second phase 12 can be confirmed with TEM-EDX. That a specific element is relatively contained only in either of the phases indicates that, based on the number of atoms, the specific element content of one phase is more than ten times the specific element content of the other phase. In that situation, the other phase with a lower specific element content is deemed not to contain the specific element.

Methods of quantifying the N content and the O content of the nanogranular magnetic film 1 as a whole are not limited. They can be quantified using, for example, an impulse heat melting extraction method. A value given by dividing the nitrogen concentration of the nanogranular magnetic film 1 by the total of the oxygen concentration and the nitrogen concentration of the nanogranular magnetic film 1 (which may hereinafter be simply referred to as “nitrogen/(oxygen+nitrogen)”) may be, for example, based on the number of atoms, 0.090 or more and 0.50 or less, or 0.10 or more and 0.50 or less. In a situation where only the second phase 12 relatively contains oxygen and nitrogen, nitrogen/(oxygen+nitrogen) can be deemed equivalent to the above f/(e+f). Alternatively, the N content and the O content may be quantified using a mapping image of TEM-EDX.

Described below is a method of determining the volume ratio of the first phases 11 to the second phase 12 of the nanogranular magnetic film by combining the results of analyzing the composition of the nanogranular magnetic film using XRF and the results of measuring the ratio concerning O and N of the nanogranular magnetic film using the impulse heat melting extraction method.

The ratio concerning the total number of oxygen atoms in an M oxide contained in the second phase 12 and the total number of nitrogen atoms in an M nitride contained in the second phase 12 can be deemed the same as the ratio concerning O and N found using the impulse heat melting extraction method. Accordingly, the volume V₂ of the second phase can be determined using the M concentration found from the XRF measurement, the ratio of the M oxide to the M nitride found using the impulse heat melting extraction method, the composition of the M oxide, the molar mass of the M oxide, the density of the M oxide, the composition of the M nitride, the molar mass of the M nitride, and the density of the M nitride. The volume V₁ of the first phases 11 can be determined using the results of the XRF composition analysis, the composition of atoms contained in the first phases 11, the molar mass of the atoms contained in the first phases 11, and the density of the first phases 11. Thus, the volume ratio of the first phases to the second phase can be determined.

One or more crystallites included in the first phases 11 have a crystal structure. The crystal structure easily increases the saturation magnetic flux density Bs.

Methods of checking the crystal structure of the one or more crystallites in the first phases 11 are not limited. The crystal structure can be checked using, for example, an X-ray diffraction pattern analysis with XRD or an electron diffraction pattern analysis with a TEM or the like.

The nanogranular magnetic film 1 may include only the first phases 11 and the second phase 12 but may further include different phases besides the first phases 11 and the second phase 12. The proportion of the different phases is not limited. The different phases may occupy an area fraction of 10% or less in a cross section of the nanogranular magnetic film 1 observed with a TEM. The different phases may partly or entirely be voids.

As shown in FIG. 1, all the first phases 11 may be distanced from each other; however, some first phases 11 may be in contact with each other. At that time, a pair or a group of grains in contact with each other as one collective grain needs to have an average circle equivalent diameter of 30 nm or less found using the areas of the grains.

The one or more crystallites in the nanogranular magnetic film 1 have crystallite sizes with a mode of 1.5 nm or more and 6.0 nm or less based on volume. The one or more crystallites in the nanogranular magnetic film 1 may have crystallite sizes with a mode of 2.0 nm or more and 5.0 nm or less based on volume. The above range of the mode of the crystallite sizes of the crystallites in the nanogranular magnetic film 1 based on volume increases the saturation magnetic flux density Bs, increases the real part of complex permeability, and reduces tan δ (dissipation factor) of the nanogranular magnetic film 1. Hereinafter, simply called “permeability” refers to the real part of complex permeability unless otherwise specified.

Described below is a method of measuring the mode of the crystallite sizes of the crystallites in the nanogranular magnetic film 1 based on volume.

Conventionally, to check a distribution of crystallite sizes of crystallites of a nanogranular magnetic film, a cross section of the nanogranular magnetic film has been observed with a TEM, and circle equivalent diameters of the crystallites in a field of view have been deemed to be the crystallite sizes.

However, observation with a TEM costs a lot financially and timewise.

Moreover, to measure the crystallite sizes of the about-several-nm-sized crystallites with a TEM, the observation magnification needs to be high. However, in observation at a high magnification, a fewer number of crystallites can have their crystallite sizes measured. Thus, it is difficult to measure the crystallite sizes of an enough number of crystallites for providing an accurate crystallite size distribution.

In a situation where observation with a TEM is carried out, microsampling, in which FIB is used to machine a sample to a thickness of 10 to 50 nm, needs to be carried out. A transmission image of the sample resulting from microsampling needs to be obtained. Because the mode of the crystallite sizes of the crystallites in the nanogranular magnetic film 1 based on volume is nanoscale, the first phases 11 may overlap in a transmission direction of an electron beam. The overlap of the first phases 11 in the transmission direction of the electron beam may make the crystallites in the first phases 11 look larger than their actual sizes. Also, a surface side of the first phases 11 at a surface layer of the sample resulting from microsampling may be, due to machining, shaved off. Thus, the crystallites in the first phases 11 at the surface layer of the sample may look smaller than their actual sizes.

For the above reasons, it is difficult to accurately measure the crystallite sizes of the crystallites in the first phases 11 through observation of the nanogranular magnetic film 1 with a TEM.

As for powder particles included in a powder, it is easy to measure a distribution of particle sizes based on volume to find the mode using a particle size measuring apparatus. However, it has conventionally been difficult to find the mode of a distribution of the crystallite sizes of the crystallites in the nanogranular magnetic film 1 based on volume.

In X-ray fluorescence (XRF) or X-ray diffraction (XRD), a fundamental parameter method (FP method) may generally be used for an analysis of an unknown sample or a sample whose reference sample is difficult to be prepared.

In the present embodiment, an analysis, with the FP method, of the results of measuring the nanogranular magnetic film 1 using X-ray diffraction (XRD) can provide the distribution of the crystallite sizes of the crystallites based on volume, allowing measurement of the mode.

Hereinafter, a method of obtaining the distribution of the crystallite sizes of the crystallites and a method of measuring the mode are described.

First, X-ray diffraction on the nanogranular magnetic film 1 is performed using an X-ray diffraction apparatus in 2θ=30° to 70° with a step size of 0.02° to obtain a diffraction chart.

Analyzing the diffraction chart using the FP method creates a histogram representing the grain size distribution of the crystallite sizes of the crystallites based on volume.

In the diffraction chart, peaks (crystal peaks and/or halo patterns) are included. First, in the diffraction chart, peaks observed in 2θ=44° to 45° are determined. This is because peaks attributed to at least some nanoscale metal grains are observed around 2θ=44° to 45°.

Then, peaks included in 2θ=30° to 70° of the diffraction chart are determined. Methods of determining the peaks are not limited. The peaks may be determined using, for example, a peak search function of analysis software. Moreover, peaks that have not been determined by the analysis software may be manually added as necessary.

Then, a background is appropriately controlled so that all the peaks attributed to the nanoscale metal grains are included in the diffraction chart, i.e., the background and the peaks attributed to the nanoscale metal grains are separated. In other words, the peaks attributed to the nanoscale metal grains are prevented from appearing below the background.

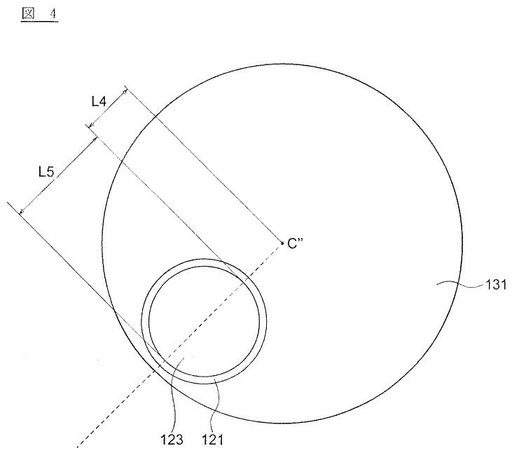

FIGS. 5 to 7 are schematic views of diffraction charts in 2θ=35° to 55°. There seems to be one wide peak in FIGS. 5 to 7. This is because FIGS. 5 to 7 are the schematic views illustrative of a background.

In FIG. 5, 2θ=36° and 2θ=54° are connected with a straight line. Because no peak attributed to a nanoscale metal grain appears below the straight line in FIG. 5, the straight line connecting 2θ=36° and 2θ=54° may be deemed to be a formal background.

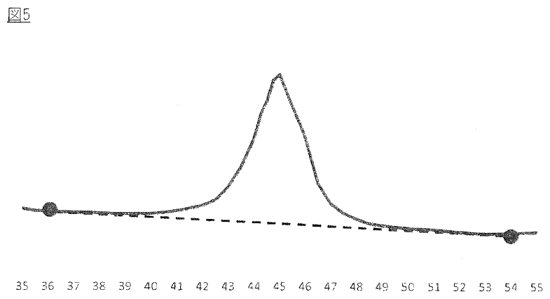

In FIG. 6, a peak attributed to a nanoscale metal grain appears below a straight line connecting 2θ=36° and 2θ=54°, unlike in FIG. 5. In this situation, the straight line connecting 2θ=36° and 2θ=54° cannot be deemed to be a formal background.

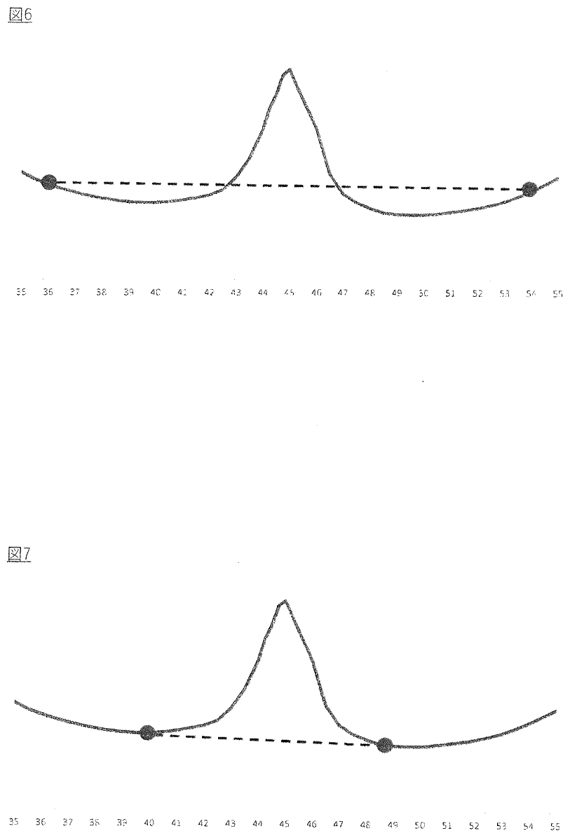

In the case of FIG. 6, the straight line connecting 2θ=36° and 2θ=54° is deemed to be a temporary background, and the temporary background is controlled to determine a straight line as a formal background as shown in FIG. 7.

Specifically, after 2θ=36° and 2θ=54° are connected with the straight line as the temporary background, the height of this temporary background is appropriately controlled to determine the straight line to be the formal background. Methods of controlling the height of the temporary background are not limited. The height may be controlled, for example, using a background refining function of the analysis software or manually. Then, in the range of 2θ=35° to 55°, refinement is performed. FIGS. 6 and 7 being compared, the shapes of the diffraction charts look slightly different. This is because the use of the background refining function has changed the look.

From the peaks attributed to the nanoscale crystal grains, the type of the crystal phases having the peaks is hypothesized. Then, in the range of 2θ=35° to 55°, refinement may be performed again. From the type of the crystal phases and the peaks, the sizes of the crystallites in the crystal phases can be found. Thus, the crystallite size distribution based on volume can be obtained.

Then, from the crystallite size distribution based on volume, a histogram is created. From the created histogram, the mode of the crystallite sizes of the crystallites can be confirmed.

In creation of the histogram, intervals between crystallite sizes are not limited; however, the intervals are small enough for sufficiently accurate confirmation of the mode of the crystallite sizes of the crystallites.

The nanogranular magnetic film 1 may have any thickness. The thickness may be, for example, 50 nm or more and 100,000 nm or less (50 nm or more and 100 μm or less). A suitable thickness may be appropriately selected according to a use. Methods of measuring the thickness of the nanogranular magnetic film 1 are not limited. The thickness can be measured with, for example, a TEM, a SEM, or a surface profiler. Also, multiple measurement apparatuses may be correlated in advance to confirm reliability of resultant measurement results.

Hereinafter, a method of manufacturing the nanogranular magnetic film according to the present embodiment is described.

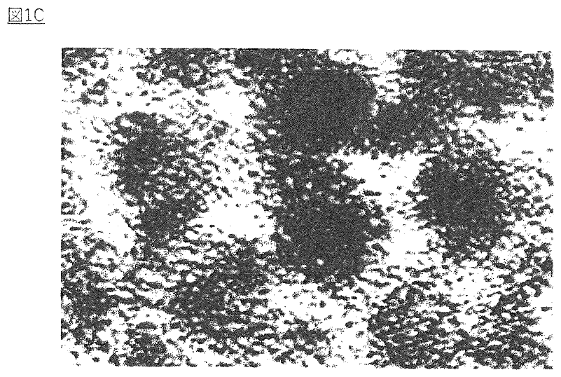

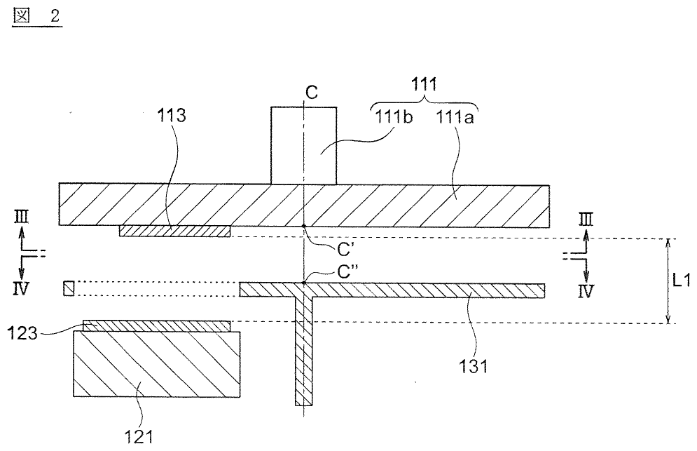

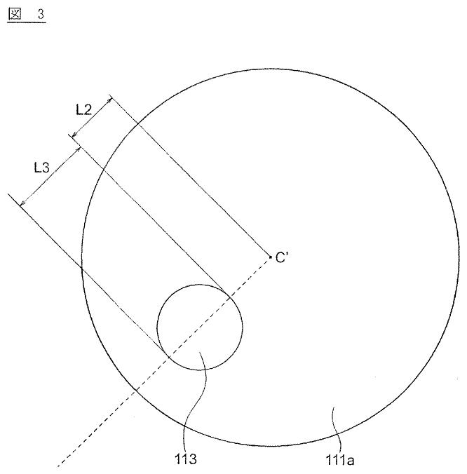

The nanogranular magnetic film according to the present embodiment is manufactured, using, for example, a sputtering method with a manufacturing apparatus shown in FIGS. 2 to 4. FIG. 2 is a cross-sectional schematic view of the manufacturing apparatus. FIG. 3 is a schematic view of the manufacturing apparatus (in particular, a rotation plate 111a and a substrate 113) viewed along the direction indicated by the arrow of a line III-III shown in FIG. 2. FIG. 4 is a schematic view of the manufacturing apparatus (in particular, a shutter 131 and a sputtering target 123) viewed along the direction indicated by the arrow of a line IV-IV shown in FIG. 2.

The substrate 113 on which to sputter the nanogranular magnetic film is fixed to the rotation plate 111a of a rotation member 111. The rotation plate 111a is fixed to a rotation axis 111b.

A substrate used as the substrate 113 on which to sputter the nanogranular magnetic film may be of any type. Examples of such substrates include a silicon substrate, a silicon substrate having an oxide film, a MgO substrate, a (non-magnetic) ferrite substrate, a sapphire substrate, a glass substrate, a super white glass substrate, and a glass epoxy substrate. However, the substrate is not limited to these substrates. Any of various ceramic substrates or various semiconductor substrates can be used.

On the above various substrates, constituent members (e.g., a coil or wiring) of a product or a component (e.g., thin film inductor) may be provided. A substrate of a thin film inductor may be provided with, for example, a coil pattern or a wiring pattern for the thin film inductor.

Alternatively, instead of the above various substrates, foil or a sheet of metal, resin, or the like can be used as the substrate 113. For example, foil of metal (e.g., Ni, Cu, and Al) can be used as the substrate 113.

Preferred as preprocessing of the substrate 113 are a surface treatment with a UV/O₃ method under normal pressure and a surface treatment in a vacuum (e.g., reverse sputtering, ion milling, and plasma cleaning). Because a magnetic film for a thin film inductor has a large film thickness, peeling-off of the film due to stress is highly problematic. However, performing both of the above surface treatments greatly improves this peeling-off of the film. The amount of time of each surface treatment is not limited. The treatment time of the UV/O₃ method may be, for example, 0.1 minutes or more and 60 minutes or less. In a situation where reverse sputtering is performed as the surface treatment in a vacuum, the reverse sputtering time may be 0.1 minutes or more and 60 minutes or less.

Shapes of the rotation plate 111a and the shutter 131 shown in FIGS. 3 and 4 are not limited. Their outer circumferential shapes may be, for example, a perfect circle. An intersection of a dashed line C and a surface of the rotation plate 111a provided with the substrate 113 in FIG. 2 is denoted by point C′. An intersection of the dashed line C and the shutter 131 in FIG. 2 is denoted by point C″. Point C′ is a center of the rotation plate 111a having a perfectly circular outer circumference. Point C″ is a center of the shutter 131 having a perfectly circular outer circumference.

The sputtering target 123 is attached to a cathode 121. The sputtering target 123 may be of any type. A composition that can eventually provide the magnetic film with an intended composition is appropriately selected.

The cathode 121 included in the sputtering apparatus may be of any type provided that the nanogranular magnetic film can be deposited on the substrate 113 using sputtering.

As shown in FIG. 4, the shutter 131 has a hole above the sputtering target 123.

Then, rotating film deposition is performed. Specifically, rotation of the rotation axis 111b rotates the rotation plate 111a for sputtering. This intermittently deposits the nanogranular magnetic film on the substrate 113. A pseudo-multilayer of the nanogranular magnetic film is thus formed. That is, in the rotating film deposition, repeating a film depositing step of depositing the nanogranular magnetic film and a mitigating step of not depositing the nanogranular magnetic film forms the pseudo-multilayer of the nanogranular magnetic film.

In the rotating film deposition, appropriately controlling the rotation speed of the rotation plate 111a, lengths L1 to L5, or the like changes the time during which the nanogranular magnetic film is deposited on the substrate 113. Appropriately controlling the positional relation between the sputtering target 123 and the substrate 113 changes the sputtering speed, changing the smallest angle of incidence of sputtering particles sputtered on the substrate 113. These changes change the film deposition time per layer of the pseudo-multilayer of the nanogranular magnetic film (which may hereinafter be referred to as continuous film deposition time) or the film thickness per layer of the pseudo-multilayer of the nanogranular magnetic film (which may hereinafter be referred to as continuously deposited film thickness).

Because locations of boundaries between layers cannot be actually confirmed even with a TEM or the like, the term “pseudo-multilayer” is used. Formation of the pseudo-multilayer of the nanogranular magnetic film provides a nanogranular magnetic film including crystallites having crystallite sizes with a mode of 1.5 nm or more and 6.0 nm or less based on volume. Various characteristics of the resultant nanogranular magnetic film are improved. Its reason is not clear; however, it is assumed that the reason is that intermittent deposition of the nanogranular magnetic film mitigates stress in the nanogranular magnetic film.

The continuous film deposition time and the continuously deposited film thickness are not limited. The continuous film deposition time may be 0.7 seconds or more and 5.0 seconds or less. The continuously deposited film thickness may be 0.4 nm or more and 3.0 nm or less.

To suitably control nitrogen/(oxygen+nitrogen) of the second phase in particular, the nitrogen concentration and the oxygen concentration of a process gas used for sputtering are preferably controlled. Specifically, preferred as the process gas is a gas containing an inert gas (e.g., a noble gas such as Ar, Kr, Xe, and Ne) mixed with nitrogen and oxygen. In the present embodiment, particularly preferred is a gas containing 2 vol % or more and 10 vol % or less nitrogen and 0.001 vol % or more and 0.1 vol % or less oxygen.

An optimum nitrogen concentration and an optimum oxygen concentration of the process gas depend on a structure of the sputtering apparatus and/or a structure of the cathode 121 included in the sputtering apparatus. What is important is N/(N+O) of the composition of the nanogranular magnetic film eventually obtained. The nitrogen concentration and the oxygen concentration of the process gas are controlled so that the composition of the nanogranular magnetic film eventually obtained has an intended value of N/(N+O).

Performing a heat treatment on the nanogranular magnetic film formed using sputtering while a magnetic field is applied thereto can make the first phases suitably include crystal grains. The heat treatment temperature is not limited. The heat treatment temperature may be, for example, 350° C. to 400° C. The heat treatment time is not limited. The heat treatment time may be, for example, 0.1 hours to 10 hours. The magnitude of the magnetic field is not limited. The magnitude of the magnetic field may be, for example, 0.1 kOe or more and 30 kOe or less. The higher the heat treatment temperature and the longer the heat treatment time, the larger the crystallite sizes of the crystallites tend to be.

In particular, in a situation where a gas containing 6 vol % or more and 7 vol % or less nitrogen and 0.1 vol % or less oxygen is used and the heat treatment temperature is 380° C. to 400° C., the mode of the crystallite sizes is prevented from increasing along with an increase in the volume fraction of the first phases. Consequently, even if the volume fraction of the first phases is increased, the nanogranular magnetic film with good characteristics is easily provided.

Hereinabove, one embodiment of the present disclosure has been described; however, the present disclosure is not limited to the above embodiment. For example, while the cathode is fixed whereas the substrate is rotated in the above method of manufacture, any method of manufacture besides the method in which either the substrate or the cathode is rotated may be used, provided that the pseudo-multilayer of the nanogranular magnetic film can be formed.

Uses of the nanogranular magnetic film according to the present embodiment are not limited. The nanogranular magnetic film and/or a magnetic core including the nanogranular magnetic film is particularly suitably included in an electronic component that operates at a frequency not lower than 100 MHz.

### EXAMPLES

The present disclosure is specifically described below based on examples. Hereinafter, the film thickness of a nanogranular magnetic film resulting from rotating film deposition indicates the total film thickness of a pseudo-multilayer of the nanogranular magnetic film. In Experiments with no specific description of the film thickness of the nanogranular magnetic film, the film was deposited so that the film thickness was within a range of 1.70 μm±10%. As described later, in Experiments with no specific description of the film thickness of the nanogranular magnetic film, the target film thickness was 1.70 μm. A reason why the target film thickness was 1.70 μm was to stably measure permeability of samples with a low permeability (e.g., about 10).

### Experiment 1

A nanogranular magnetic film was deposited on a substrate using an apparatus shown in FIGS. 2 to 4. L1=90 mm, L2=2 inches, L3=3 inches, L4=2 inches, and L5=4 inches were satisfied. A sputtering target having a composition that provided the nanogranular magnetic film with a composition shown in each table and having a thickness of 2 mm was attached to a cathode of the sputtering apparatus. As the sputtering apparatus, SPF430H (manufactured by ANELVA Corporation) was used. The composition of the thin film shown in each table is rounded off to the nearest whole number. Thus, element contents may not add up to a total of 100.

As a substrate for evaluation of various characteristics, a φ2-inch, 0.28-mm-thick silicon substrate with a thermal oxide film was used. As a substrate for a composition analysis, a φ2-inch sapphire substrate having a thickness of 0.28 mm was used. As a substrate for nitrogen/oxygen measurement, 50-mm squared Ni foil having a thickness of 50 μm (0.05 mm) was used. As a substrate for step height measurement, a silicon substrate having a straight line drawn on a surface using a resist pen and having a thickness of 0.28 mm was used.

The line drawn with the resist pen on the surface was, specifically, a straight line perpendicular to an orientation flat of the silicon substrate from a center of the orientation flat to the opposite of the orientation flat. A resist was formed where the straight line was drawn with the resist pen.

To the substrates other than the silicon substrate for step height measurement, a surface treatment using a UV/O₃ method was performed for 30 minutes as preprocessing.

Then, all the substrates were attached to centers of φ3-inch silicon substrates having a thickness of 0.5 mm and were then introduced in the sputtering apparatus. Its chamber was vacuumed. Reverse sputtering was performed for 5 minutes. The atmosphere was an Ar gas under pressure of 1 Pa. RF power output was 100 W. In Comparative Example 6, neither preprocessing nor reverse sputtering was performed.

After the film deposition chamber of the sputtering apparatus was re-exhausted, on all the substrates, the nanogranular magnetic film was deposited using a sputtering method. RF power output was 400 W. A process gas that flowed during film deposition was a gas containing an Ar gas mixed with a nitrogen gas and/or an oxygen gas at a nitrogen concentration and an oxygen concentration shown in each table. Lack of such description in each table indicates that the nitrogen concentration was 4 vol % whereas the oxygen concentration was 0.01 vol %.

In all Examples and Comparative Examples other than Comparative Example 5, a rotation plate was rotated during sputtering. The rotation speed was 12 rpm. The continuous film deposition time was 1.7 s. The continuously deposited film thickness was 1.0 nm.

### (Film Thickness)

The film-deposited substrate for step height measurement was immersed in acetone. With an ultrasonic cleaning apparatus, lift-off was performed to remove the resist from the substrate. The substrate having the resist removed was immersed in isopropanol (IPA) and was cleaned with the ultrasonic cleaning apparatus. Then, an organic solvent remaining on the substrate was removed with a nitrogen blow to dry the substrate. Then, with a surface profiler (KLA Tencor P-16+), the step height was measured at a total of five points, which were a center point of the substrate, points at locations away from the center point of the substrate by ±75 mm, and points at locations away from the center point of the substrate by ±150 mm. Their average step height value was deemed to be the film thickness of all thin films deposited simultaneously. In all Examples and Comparative Examples, it was confirmed that the film thickness of the thin film was within ±10% or less of the target film thickness (1.70 μm unless otherwise specified).

$$( Nitrogen / ( oxygen + nitrogen ) )$$

The substrate for nitrogen/(oxygen+nitrogen) measurement was heat treated in a vacuum with magnetic field heat treatment equipment (manufactured by Toei Scientific Industrial Co., Ltd.). Heat treatment conditions were as follows unless otherwise specified. The treatment temperature was 400° C. The treatment time was 1 hour. The applied magnetic field was 3 kOe.

The substrate for nitrogen/oxygen measurement after being heat treated was cut so as to have an area of 3 cm². The cut substrate was packed in a capsule to measure nitrogen/(oxygen+nitrogen) with an impulse heat melting extraction method. For the impulse heat melting extraction method, an oxygen nitrogen analyzing apparatus (TC600 manufactured by LECO JAPAN CORPORATION) was used.

### (Composition)

The composition of first phases, the composition of a second phase, and V₁/(V₁+V₂) were checked using XRF (Primus IV manufactured by Rigaku Holdings Corporation) on the heat treated thin film deposited on the substrate for the composition analysis.

A specific method of checking V₁/(V₁+V₂) used in the present Examples is described below. First, it was hypothesized that all elements applicable to M (e.g., Si, Al, Ga, Mg, Zr, Hf, and a rare earth element) of the second phase quantified using XRF were present in the second phase as an oxide or a nitride and that other elements (excluding oxygen, nitrogen, and fluorine (=light elements)) were present in the first phases. In Experiments described later other than Experiment 4, M was Si. The ratio concerning O and N of the nanogranular magnetic film deposited on the Ni foil, which went through film deposition and the heat treatment simultaneously with the substrate for the composition analysis, was measured using the impulse heat melting extraction method. It was hypothesized that all elements of M of the second phase were oxidized or nitrated. Using the ratio of an M oxide to an M nitride, the composition of the M oxide, the molar mass of the M oxide, the density of the M oxide, the composition of the M nitride, the molar mass of the M nitride, and the density of the M nitride, the volume V₂ of the second phase was calculated. Using the results of the XRF composition analysis, the composition of atoms contained in the first phases 11, the molar mass of the atoms contained in the first phases, and the density of the first phases, the volume V₁ of the first phases was calculated. Then, V₁/(V₁+V₂) was found.

### (Characteristics)

The film-deposited substrate for evaluation of various characteristics cut into 6-mm square was heat treated in a vacuum with magnetic field heat treatment equipment (manufactured by Toei Scientific Industrial Co., Ltd.). Heat treatment conditions were as follows unless otherwise specified. The treatment temperature was 400° C. The treatment time was 1 hour. The applied magnetic field was 3 kOe.

Using a VSM (TM-VSM331483-HGC manufactured by TAMAKAWA CO., LTD.), saturation magnetic flux density Bs of the magnetic film on the heat-treated substrate for evaluation of various characteristics was measured. Specifically, B-H characteristics were obtained at a maximum applied magnetic field of 10000 Oe with the VSM, and Bs was calculated from the resultant B-H characteristics. Bs was deemed good when Bs was 0.75 T or more.

Specific resistance of the magnetic film on the heat-treated substrate for evaluation of various characteristics was calculated from sheet resistance obtained using Loresta EP manufactured by Mitsubishi Chemical Corporation and the film thickness. Specific resistance was deemed good when it was 500 μΩcm or more or was deemed better when it was 1000 μΩcm or more.

Permeability and tan δ (dissipation factor) were measured using a permeance meter (PMF-3000 manufactured by Ryowa Electronics Co., Ltd.). As for permeability and tan δ, values at a measurement frequency of 100 MHz were adopted. Permeability was deemed good when it was 80 or more whereas tan δ was deemed good when it was 0.100 or less.

The mode of the crystallite sizes of crystallites of the present Examples was measured as follows. First, X-ray diffraction on the nanogranular magnetic film on the heat-treated substrate for evaluation of various characteristics was performed using an X-ray diffraction apparatus (SmartLab Studio II manufactured by Rigaku Holdings Corporation) in 2θ=30° to 70° with a step size of 0.02° to obtain a diffraction chart.

The diffraction chart resulting from X-ray diffraction was analyzed using an FP method to create a histogram representing the grain size distribution of the crystallite sizes of the crystallites based on volume.

The analysis using the FP method was performed with “Powder XRD” included in the X-ray diffraction apparatus. In the present Examples, first, peaks observed in 44° to 45° in the diffraction chart were determined. Then, peaks in 2θ=30° to 70° in the diffraction chart were determined using a peak search function of analysis software. Moreover, peaks that were not determined by the analysis software were manually added by sight as necessary. Then, a background was appropriately controlled so that all peaks attributed to the nanoscale metal grains observed in the diffraction chart were included in the diffraction chart. Specifically, after 2θ=36° and 2θ=54° were connected with a straight line as a temporary background, the height of this temporary background was controlled as necessary. To control the height of the temporary background, a background refining function of the analysis software was used.

Then, an axial divergence model of an FP model of an apparatus model of “Powder XRD” was set to Ida; a profile fitting peak shape was set to FP method; and a crystallite size distribution type was set to log-normal distribution.

Then, crystal phases were identified. Specifically, first, the type of the crystal phases was hypothesized. It was hypothesized that the crystal phases were those having a body-centered cubic structure composed of any one of Fe, FeCo, or FeNi according to the composition of each sample. Specifically, it was hypothesized that the crystal phases applied to DB card No. 01-071-7173. Then, within the range of 35° to 55°, refinement was performed again to identify the sizes of the crystallites included in each crystal phase from the type and a crystal peak of the crystal phase. A crystallite size distribution based on volume was thus obtained.

Then, from the crystallite size distribution based on volume, a histogram was created. Using the resultant histogram, the mode was confirmed. In creation of the histogram, intervals between crystallite sizes were small enough. In the present Examples, the intervals were 0.05 nm or less.

Table 1 shows Examples and Comparative Examples in which film deposition conditions were changed to change the mode of the crystallite sizes of the crystallites.

TABLE 1

| | | | | | Thin film composition | | | | | | | |
|---|---|---|---|---|---|---|---|---|---|---|---|---|
| | Film deposition condition | | | | | Whole | | | | | | |
| | | | Process gas | | Light | | Nitrogen/ | Crystal- | | | | |
| | | | Nitrogen | Oxygen | elements | V₁/ | (nitrogen + | lite | Characteristics | | | |
| | | | concen- | concen- | excluded | (V₁ + | oxygen) | Size | | Specific | Perme- | |
| Sample | Pre- | | tration | tration | Composition | V₂) | Atomic | Mode | Bs | resistance | ability | |
| No. | processing | Rotation | vol % | vol % | Atomic ratio | % | ratio | nm | T | μΩcm | μ′ | tanδ |
| Comparative | Yes | Yes | 0 | 0.01 | Fe₄₈Co₃₃Si₁₉ | 56 | 0 | 6.8 | 1.06 | 18500 | 120 | 0.161 |
| Example 1 | | | | | | | | | | | | |
| Comparative | Yes | Yes | 1 | 0.01 | Fe₄₈Co₃₃Si₁₈ | 57 | 0.082 | 6.4 | 0.96 | 7200 | 121 | 0.147 |
| Example 2 | | | | | | | | | | | | |
| Comparative | Yes | Yes | 3 | 0 | Fe₄₈Co₃₄Si₁₈ | 58 | 0.296 | 7.2 | 0.92 | 950 | 119 | 0.135 |
| Example 3 | | | | | | | | | | | | |
| Example 1 | Yes | Yes | 3 | 0.001 | Fe₄₈Co₃₄Si₁₈ | 58 | 0.290 | 5.9 | 0.92 | 1100 | 119 | 0.095 |
| Example 2 | Yes | Yes | 3 | 0.005 | Fe₄₈Co₃₄Si₁₈ | 58 | 0.285 | 3.8 | 0.91 | 1400 | 117 | 0.079 |
| Example 3 | Yes | Yes | 3 | 0.01 | Fe₄₈Co₃₄Si₁₈ | 58 | 0.274 | 2.7 | 0.91 | 2700 | 117 | 0.062 |
| Example 4 | Yes | Yes | 3 | 0.03 | Fe₄₈Co₃₃Si₁₈ | 57 | 0.231 | 2.3 | 0.86 | 5400 | 108 | 0.077 |
| Example 5 | Yes | Yes | 3 | 0.05 | Fe₄₈Co₃₃Si₁₈ | 57 | 0.182 | 1.8 | 0.81 | 20400 | 102 | 0.083 |
| Example 6 | Yes | Yes | 3 | 0.07 | Fe₄₈Co₃₃Si₁₈ | 57 | 0.099 | 1.5 | 0.77 | 31600 | 90 | 0.094 |
| Example 6a | Yes | Yes | 3 | 0.09 | Fe₄₈Co₃₃Si₁₈ | 57 | 0.065 | 1.5 | 0.75 | 37700 | 80 | 0.098 |
| Comparative | Yes | Yes | 3 | 0.10 | Fe₄₈Co₃₃Si₁₈ | 57 | 0.047 | 1.3 | 0.38 | 113000 | 27 | 0.184 |
| Example 4 | | | | | | | | | | | | |
| Comparative | Yes | No | 3 | 0.01 | Fe₄₉Co₃₄Si₁₇ | 59 | 0.425 | 1.2 | 0.64 | 5900 | 73 | 0.150 |
| Example 5 | | | | | | | | | | | | |
| Comparative | No | Yes | 3 | 0.01 | Fe₄₉Co₃₄Si₁₇ | Film peeling-off | | | | | | |
| Example 6 | | | | | | | | | | | | |

According to Table 1, Examples 1 to 6 and 6a, in which the nanogranular magnetic film had a composition within a specific range and the mode of the crystallite sizes of the crystallites was within a predetermined range, had good characteristics.

In contrast, in Comparative Examples 1 and 2, in which the nitrogen concentration of the process gas was relatively too low, the mode of the crystallite sizes of the crystallites was large. In Comparative Examples 1 and 2, tan δ was too high.

In Comparative Example 3, in which the oxygen concentration of the process gas was relatively too low, the mode of the crystallite sizes of the crystallites was large. In Comparative Example 3, tan δ was too high.

In Comparative Example 4, in which the oxygen concentration of the process gas was relatively too high, the mode of the crystallite sizes of the crystallites was small. In Comparative Example 4, Bs and permeability were too low whereas tan δ was too high.

In Comparative Example 5, in which the film was deposited without substrate rotation and did not have the pseudo-multilayer, Bs and permeability were too low whereas tan δ was too high.

In Comparative Example 6, in which neither the surface treatment using the UV/O₃ method nor reverse sputtering was performed, the magnetic film was not sufficiently adhered to the substrate, resulting in peeling-off.

Table 2 shows Examples 7 to 11, which were carried out as in Examples 1 to 3 and 5 to 6 except that V₁/(V₁+V₂) was changed to 47%. Table 2 also shows Examples 12 to 16, which were carried out as in Examples 1 to 3 and 5 to 6 except that V₁/(V₁+V₂) was changed to 72%.

TABLE 2

| | | | | | Thin film composition | | | | | | | |
|---|---|---|---|---|---|---|---|---|---|---|---|---|
| | Film deposition condition | | | | | Whole | | | | | | |
| | | | Process gas | | Light | | Nitrogen/ | | | | | |
| | | | Nitrogen | Oxygen | elements | V₁/ | (nitrogen + | Crystallite | Characteristics | | | |
| | | | concen- | concen- | excluded | (V₁ + | oxygen) | size | | Specific | Perme- | |
| Sample | Pre- | | tration | tration | Composition | V₂) | Atomic | Mode | Bs | resistance | ability | |
| No. | processing | Rotation | vol % | vol % | Atomic ratio | % | ratio | nm | T | μΩcm | μ′ | tanδ |
| Example 7 | Yes | Yes | 3 | 0.001 | Fe₄₅Co₃₁Si₂₄ | 47 | 0.322 | 5.8 | 0.90 | 6000 | 89 | 0.099 |
| Example 8 | Yes | Yes | 3 | 0.005 | Fe₄₅Co₃₁Si₂₄ | 47 | 0.302 | 3.6 | 0.86 | 8900 | 84 | 0.098 |
| Example 9 | Yes | Yes | 3 | 0.01 | Fe₄₅Co₃₁Si₂₄ | 47 | 0.280 | 2.5 | 0.84 | 12900 | 83 | 0.096 |
| Example 10 | Yes | Yes | 3 | 0.05 | Fe₄₅Co₃₁Si₂₄ | 47 | 0.173 | 1.6 | 0.79 | 83000 | 83 | 0.097 |
| Example 11 | Yes | Yes | 3 | 0.07 | Fe₄₅Co₃₁Si₂₄ | 47 | 0.098 | 1.5 | 0.75 | 145000 | 81 | 0.099 |
| Example 1 | Yes | Yes | 3 | 0.001 | Fe₄₈Co₃₄Si₁₈ | 58 | 0.290 | 5.9 | 0.92 | 1100 | 119 | 0.095 |
| Example 2 | Yes | Yes | 3 | 0.005 | Fe₄₈Co₃₄Si₁₈ | 58 | 0.285 | 3.8 | 0.91 | 1400 | 117 | 0.079 |
| Example 3 | Yes | Yes | 3 | 0.01 | Fe₄₈Co₃₄Si₁₈ | 58 | 0.274 | 2.7 | 0.91 | 2700 | 117 | 0.062 |
| Example 5 | Yes | Yes | 3 | 0.05 | Fe₄₈Co₃₃Si₁₈ | 57 | 0.182 | 1.8 | 0.81 | 20400 | 102 | 0.083 |
| Example 6 | Yes | Yes | 3 | 0.07 | Fe₄₈Co₃₃Si₁₈ | 57 | 0.099 | 1.5 | 0.77 | 31600 | 90 | 0.094 |
| Example 12 | Yes | Yes | 3 | 0.001 | Fe₅₄Co₃₆Si₁₀ | 72 | 0.286 | 6.0 | 1.14 | 1000 | 110 | 0.099 |
| Example 13 | Yes | Yes | 3 | 0.005 | Fe₅₄Co₃₆Si₁₀ | 72 | 0.281 | 4.5 | 1.12 | 1100 | 112 | 0.098 |
| Example 14 | Yes | Yes | 3 | 0.01 | Fe₅₄Co₃₆Si₁₀ | 72 | 0.272 | 3.3 | 1.10 | 2100 | 112 | 0.096 |
| Example 15 | Yes | Yes | 3 | 0.05 | Fe₅₄Co₃₆Si₁₀ | 72 | 0.185 | 2.0 | 0.93 | 14200 | 100 | 0.097 |
| Example 16 | Yes | Yes | 3 | 0.07 | Fe₅₄Co₃₆Si₁₀ | 72 | 0.112 | 1.6 | 0.84 | 20800 | 87 | 0.098 |

According to Table 2, Examples 7 to 16, in which the nanogranular magnetic film had a composition within the specific range and the mode of the crystallite sizes of the crystallites was within the predetermined range, had good characteristics similarly to Examples 1 to 3 and 5 to 6.

### Experiment 2

Table 3 shows Examples and Comparative Examples carried out as in Example 3 of Experiment 1 except that the nitrogen concentration of the process gas was changed and that further the heat treatment temperature was changed to a temperature shown in Table 3. Note that FIGS. 1A to 1C are STEM cross-sectional images of Example 19.

TABLE 3

| | | | | Thin film composition | | | | | | | |
|---|---|---|---|---|---|---|---|---|---|---|---|
| | Film deposition condition | | | | Whole | | | | | | |
| | Process gas | | Heat | Light | | Nitrogen/ | Crystal- | | | | |
| | Nitrogen | Oxygen | treatment | elements | V₁/ | (nitrogen + | lite | Characteristics | | | |
| | concen- | concen- | Temper- | excluded | (V₁ + | oxygen) | size | | Specific | Perme- | |
| | tration | tration | ature | Composition | V₂) | Atomic | Mode | Bs | resistance | ability | |
| Sample No. | vol % | vol % | ° C. | Atomic ratio | % | ratio | nm | T | μΩcm | μ′ | tanδ |
| Comparative | 3 | 0.01 | 350 | Fe₄₈Co₃₄Si₁₈ | 58 | 0.375 | 1.2 | 0.71 | 4200 | 59 | 0.195 |
| Example 7 | | | | | | | | | | | |
| Comparative | 3 | 0.01 | 370 | Fe₄₈Co₃₄Si₁₈ | 58 | 0.355 | 1.4 | 0.77 | 3300 | 72 | 0.127 |
| Example 8 | | | | | | | | | | | |
| Example 3 | 3 | 0.01 | 400 | Fe₄₈Co₃₄Si₁₈ | 58 | 0.274 | 2.7 | 0.91 | 2700 | 117 | 0.062 |
| Comparative | 4 | 0.01 | 350 | Fe₄₈Co₃₄Si₁₈ | 58 | 0.354 | 1.4 | 0.68 | 2900 | 91 | 0.104 |
| Example 9 | | | | | | | | | | | |
| Example 17 | 4 | 0.01 | 370 | Fe₄₈Co₃₄Si₁₈ | 58 | 0.337 | 2.3 | 0.82 | 2200 | 102 | 0.051 |
| Example 18 | 4 | 0.01 | 390 | Fe₄₈Co₃₄Si₁₈ | 58 | 0.311 | 3.0 | 0.88 | 2000 | 107 | 0.037 |
| Example 19 | 4 | 0.01 | 400 | Fe₄₈Co₃₄Si₁₈ | 58 | 0.298 | 3.4 | 0.90 | 1800 | 112 | 0.038 |
| Example 20 | 6 | 0.01 | 350 | Fe₄₈Co₃₄Si₁₈ | 58 | 0.417 | 1.9 | 0.77 | 2300 | 112 | 0.082 |
| Example 21 | 6 | 0.01 | 370 | Fe₄₈Co₃₄Si₁₈ | 58 | 0.381 | 2.6 | 0.82 | 1800 | 124 | 0.041 |
| Example 21a | 6 | 0.01 | 380 | Fe₄₈Co₃₄Si₁₈ | 58 | 0.365 | 2.7 | 0.86 | 1800 | 127 | 0.034 |
| Example 22 | 6 | 0.01 | 390 | Fe₄₈Co₃₄Si₁₈ | 58 | 0.355 | 3.1 | 0.87 | 1600 | 129 | 0.063 |
| Example 23 | 6 | 0.01 | 400 | Fe₄₈Co₃₄Si₁₈ | 58 | 0.332 | 3.3 | 0.89 | 1500 | 137 | 0.077 |
| Example 24 | 8 | 0.01 | 370 | Fe₄₈Co₃₄Si₁₈ | 58 | 0.436 | 2.5 | 0.80 | 1400 | 126 | 0.048 |
| Example 25 | 10 | 0.01 | 370 | Fe₄₈Co₃₄Si₁₈ | | 0.500 | 2.5 | 0.78 | 1200 | 132 | 0.065 |
| Example 26 | 12 | 0.01 | 370 | Fe₄₈Co₃₄Si₁₈ | 58 | 0.550 | 2.5 | 0.75 | 1000 | 130 | 0.091 |
| Example 26a | 15 | 0.01 | 370 | Fe₄₈Co₃₄Si₁₈ | 58 | 0.706 | 2.3 | 0.75 | 610 | 98 | 0.097 |

According to Table 3, Examples 17 to 26, 21a, and 26a, in which the nanogranular magnetic film had a composition within the specific range and the mode of the crystallite sizes of the crystallites was within the predetermined range, had good characteristics similarly to Example 3.

In contrast, in Comparative Examples 7 to 9, in which the mode of the crystallite sizes of the crystallites was too small, tan δ was too high. Moreover, in Comparative Examples 7 and 8, permeability was too low.

### Experiment 3

Table 4 shows Examples carried out substantially as in Example 19 of Experiment 2 except that the composition of the first phases was changed from that of Example 19. Examples 27 to 30 were samples whose FeCo ratio was changed from that of Example 19. Film deposition was performed with a sputtering target that was controlled so that V₁/(V₁+V₂) was 58%.

As for Example 31, a sample was manufactured with five Ni chips measuring 5 mm×5 mm×1 mmt placed at suitably controlled positions on the sputtering target used for Example 19 so that the composition of the first phases was Fe₅₅Co₃₅Ni₁₀.

As for Examples 32 to 52, a suitable number of metal chips or alloy chips of X1 shown in Table 4 were placed at suitably controlled positions on the sputtering target used for Example 19 so that the composition of the first phases was approximately Fe₅₉Co₃₉X1₂. Moreover, a sputtering target with a controlled composition was used to manufacture samples.

TABLE 4

| | Thin film composition | | | | | | | |
|---|---|---|---|---|---|---|---|---|
| | | Whole | | | | | | |
| | | | Nitrogen/ | | | | | |
| | Light elements | V₁/ | (nitrogen + | Crystallite | Characteristics | | | |
| | excluded | (V₁ + | oxygen) | size | | Specific | | |
| | Composition | V₂) | Atomic | Mode | Bs | resistance | Permeability | |
| Sample No. | Atomic ratio | % | ratio | nm | T | μΩcm | μ′ | tanδ |
| Example 27 | Fe₄₈Co₃₄Si₁₈ | 58 | 0.311 | 3.6 | 0.92 | 1600 | 109 | 0.049 |
| Example 28 | Fe₄₈Co₃₄Si₁₈ | 58 | 0.320 | 3.3 | 0.93 | 1700 | 115 | 0.042 |
| Example 19 | Fe₄₈Co₃₄Si₁₈ | 58 | 0.298 | 3.4 | 0.90 | 1800 | 112 | 0.038 |
| Example 29 | Fe₄₈Co₃₄Si₁₈ | 58 | 0.286 | 3.1 | 0.89 | 1800 | 104 | 0.055 |
| Example 30 | Fe₄₈Co₃₄Si₁₈ | 58 | 0.279 | 3.5 | 0.82 | 2100 | 90 | 0.079 |
| Example 31 | Fe₄₅Co₃₂Ni₆Si₁₇ | 60 | 0.315 | 3.9 | 0.86 | 1400 | 102 | 0.076 |
| Example 32 | Fe₄₇Co₃₄Ni₁Si₁₈ | 59 | 0.306 | 3.5 | 0.90 | 1600 | 110 | 0.055 |
| Example 33 | Fe₄₇Co₃₄B₁Si₁₈ | 59 | 0.271 | 2.7 | 0.87 | 1900 | 102 | 0.049 |
| Example 34 | Fe₄₇Co₃₄C₁Si₁₈ | 59 | 0.269 | 2.6 | 0.85 | 1700 | 96 | 0.056 |
| Example 35 | Fe₄₇Co₃₄P₁Si₁₈ | 59 | 0.275 | 2.6 | 0.88 | 1700 | 103 | 0.054 |
| Example 36 | Fe₄₇Co₃₄ V₁Si₁₈ | 59 | 0.299 | 3.6 | 0.88 | 1500 | 101 | 0.061 |
| Example 37 | Fe₄₇Co₃₄Cr₁Si₁₈ | 59 | 0.296 | 3.1 | 0.86 | 1600 | 102 | 0.061 |
| Example 38 | Fe₄₇Co₃₄Mn₁Si₁₈ | 59 | 0.304 | 3.3 | 0.87 | 1500 | 105 | 0.070 |
| Example 39 | Fe₄₇Co₃₄Cu₁Si₁₈ | 59 | 0.281 | 3.5 | 0.86 | 1500 | 101 | 0.067 |
| Example 40 | Fe₄₇Co₃₄Zn₁Si₁₈ | 59 | 0.285 | 2.9 | 0.87 | 1600 | 102 | 0.058 |
| Example 41 | Fe₄₇Co₃₄Nb₁Si₁₈ | 59 | 0.284 | 3.1 | 0.86 | 1600 | 104 | 0.055 |
| Example 42 | Fe₄₇Co₃₄Mo₁Si₁₈ | 59 | 0.285 | 3.3 | 0.86 | 1600 | 100 | 0.059 |
| Example 43 | Fe₄₇Co₃₄Ru₁Si₁₈ | 59 | 0.294 | 3.1 | 0.91 | 1500 | 107 | 0.072 |
| Example 44 | Fe₄₇Co₃₄Rh₁Si₁₈ | 59 | 0.292 | 3.1 | 0.90 | 1500 | 105 | 0.070 |
| Example 45 | Fe₄₇Co₃₄Pd₁Si₁₈ | 59 | 0.290 | 3.2 | 0.89 | 1500 | 101 | 0.069 |
| Example 46 | Fe₄₇Co₃₄Ag₁Si₁₈ | 59 | 0.285 | 3.4 | 0.85 | 1500 | 99 | 0.066 |
| Example 47 | Fe₄₇Co₃₄Sn₁Si₁₈ | 59 | 0.288 | 3.0 | 0.88 | 1600 | 100 | 0.062 |
| Example 48 | Fe₄₇Co₃₄Ta₁Si₁₈ | 59 | 0.292 | 3.3 | 0.85 | 1600 | 103 | 0.060 |
| Example 49 | Fe₄₇Co₃₄W₁Si₁₈ | 59 | 0.303 | 3.2 | 0.85 | 1500 | 98 | 0.064 |
| Example 50 | Fe₄₇Co₃₄Ir₁Si₁₈ | 59 | 0.287 | 3.3 | 0.90 | 1600 | 110 | 0.070 |
| Example 51 | Fe₄₇Co₃₄Pt₁Si₁₈ | 59 | 0.293 | 3.2 | 0.92 | 1500 | 118 | 0.061 |
| Example 52 | Fe₄₇Co₃₄Au₁Si₁₈ | 59 | 0.293 | 3.2 | 0.92 | 1500 | 118 | 0.061 |

According to Table 4, Examples 27 to 52, in which the mode of the crystallite sizes of the crystallites was within the predetermined range despite the addition of various elements to the nanogranular magnetic film, had good characteristics similarly to Example 19.

### Experiment 4

Tables 5, 6, and 7 show Examples carried out substantially as in Example 19 except that the sputtering target contained a specified amount of Al₂O₃, Ga₃O₄, MgF₂, MgO, ZrO₂, HfO₂, Y₂O₃, or La₂O₃ to change the composition of the second phase 12 from that of Example 19.

Table 5 shows Examples 53 to 56, in which SiO₂ contained in the sputtering target of Example 19 was partly or entirely substituted with Al₂O₃. Methods of checking the ratio concerning O and N of the nanogranular magnetic film and V₁/(V₁+V₂) were similar to those of Experiment 1 except that M included Si and/or Al.

Table 6 shows Examples 57 to 60, in which SiO₂ contained in the sputtering target of Example 19 was partly or entirely substituted with Ga₂O₃. Methods of checking the ratio concerning O and N of the nanogranular magnetic film and V₁/(V₁+V₂) were similar to those of Experiment 1 except that M included Si and/or Ga.

Table 7 shows Examples 61 to 66, in which 5 vol % of SiO₂ contained in the sputtering target of Example 19 was substituted with another compound (oxide or fluoride). Specifically, the another compound was a fluoride in Example 61 and was an oxide in Examples 62 to 66. Methods of checking the ratio concerning O and N of the nanogranular magnetic film and V₁/(V₁+V₂) were similar to those of Experiment 1 except that M included Si and Mg (Examples 61 and 62), Si and Zr (Example 63), Si and Hf (Example 64), Si and Y (Example 65), or Si and La (Example 66).

TABLE 5

| | Thin film composition | | | | | | | | |
|---|---|---|---|---|---|---|---|---|---|
| | | | Whole | | | | | | |
| | | Second phase | | Nitrogen/ | Crystal- | | | | |
| | Light elements | Si | V₁/ | (oxygen + | lite | Characteristics | | | |
| | excluded | compound:Al | (V₁ + | nitrogen) | size | | Specific | Perme- | |
| | Composition | compound | V₂) | Atomic | Mode | Bs | resistance | ability | |
| Sample No. | Atomic ratio | Volume ratio | % | ratio | nm | T | μΩcm | μ′ | tanδ |
| Example 19 | Fe₄₈Co₃₄Si₁₈ | 100:0 | 58 | 0.298 | 3.4 | 0.90 | 1800 | 112 | 0.038 |
| Example 53 | Fe₄₈Co₃₄Si₁₅Al₃ | 90:10 | 58 | 0.290 | 3.3 | 0.90 | 1700 | 110 | 0.041 |
| Example 54 | Fe₄₈Co₃₄Si₈Al₁₀ | 60:40 | 58 | 0.288 | 3.1 | 0.89 | 1600 | 107 | 0.053 |
| Example 55 | Fe₄₈Co₃₄Si₂Al₁₆ | 20:80 | 58 | 0.282 | 3.0 | 0.91 | 1500 | 107 | 0.063 |
| Example 56 | Fe₄₈Co₃₄Al₁₈ | 0:100 | 58 | 0.276 | 2.9 | 0.91 | 1500 | 108 | 0.072 |

TABLE 6

| | Thin film composition | | | | | | | | |
|---|---|---|---|---|---|---|---|---|---|
| | | | Whole | | | | | | |
| | | | | Nitrogen/ | Crystal- | | | | |
| | Light elements | Si | V₁/ | (oxygen + | lite | Characteristics | | | |
| | excluded | compound:Ga | (V₁ + | nitrogen) | size | | Specific | Perme- | |
| | Composition | compound | V₂) | Atomic | Mode | Bs | resistance | ability | |
| Sample No. | Atomic ratio | Volume ratio | % | ratio | nm | T | μΩcm | μ′ | tanδ |
| Example 19 | Fe₄₈Co₃₄Si₁₈ | 100:0 | 58 | 0.298 | 3.4 | 0.90 | 1800 | 112 | 0.038 |
| Example 57 | Fe₄₈Co₃₄Si₁₅Ga₃ | 90:10 | 58 | 0.289 | 3.2 | 0.90 | 1700 | 109 | 0.042 |
| Example 58 | Fe₄₈Co₃₄Si₉Ga₉ | 60:40 | 58 | 0.275 | 2.9 | 0.89 | 1500 | 105 | 0.055 |
| Example 59 | Fe₄₈Co₃₄Si₂Ga₁₆ | 20:80 | 58 | 0.267 | 2.7 | 0.88 | 1400 | 103 | 0.062 |
| Example 60 | Fe₄₈Co₃₄Ga₁₈ | 0:100 | 58 | 0.254 | 2.5 | 0.88 | 1300 | 102 | 0.069 |

TABLE 7

| | Thin film composition | | | | | | | | |
|---|---|---|---|---|---|---|---|---|---|
| | | Si:element | Whole | | | | | | |
| | | other than Si | | Nitrogen/ | Crystal- | | | | |
| | Light elements | (excluding | V₁/ | (oxygen + | lite | Characteristics | | | |
| | excluded | O, N, F) | (V₁ + | nitrogen) | size | | Specific | Perme- | |
| | Composition | Volume | V₂) | Atomic | Mode | Bs | resistance | ability | |
| Sample No. | Atomic ratio | ratio | % | ratio | nm | T | μΩcm | μ′ | tanδ |
| Example 19 | Fe₄₈Co₃₄Si₁₈ | 100:0 | 58 | 0.298 | 3.4 | 0.90 | 1800 | 112 | 0.038 |
| Example 61 | Fe₄₇Co₃₄Si₁₈Mg₁ | 95:5 | 58 | 0.319 | 3.2 | 0.87 | 1400 | 101 | 0.052 |
| Example 62 | Fe₄₇Co₃₄Si₁₇Mg₂ | 95:5 | 58 | 0.303 | 3.3 | 0.85 | 1500 | 99 | 0.054 |
| Example 63 | Fe₄₇Co₃₄Si₁₈Zr₁ | 95:5 | 58 | 0.302 | 3.1 | 0.86 | 1500 | 100 | 0.048 |
| Example 64 | Fe₄₇Co₃₄Si₁₈Hf₁ | 95:5 | 58 | 0.305 | 3.0 | 0.85 | 1400 | 97 | 0.051 |
| Example 65 | Fe₄₇Co₃₄Si₁₈Y₁ | 95:5 | 58 | 0.308 | 2.9 | 0.82 | 1200 | 97 | 0.053 |
| Example 66 | Fe₄₇Co₃₄Si₁₈La₁ | 95:5 | 58 | 0.310 | 2.9 | 0.83 | 1200 | 98 | 0.052 |

According to Tables 5, 6, and 7, Examples 53 to 66, in which the nanogranular magnetic film had a composition within the specific range and the mode of the crystallite sizes of the crystallites was within the predetermined range despite the changes in the composition of the second phase, had good characteristics similarly to Example 19.

### Experiment 5

Table 8 shows Examples and Comparative Examples carried out substantially as in Example 19 except that V₁/(V₁+V₂) was changed from that of Example 19. Table 9 shows Examples and Comparative Examples carried out substantially as in Example 21 except that V₁/(V₁+V₂) was changed from that of Example 21.

TABLE 8

| | Thin film composition | | | | | | | |
|---|---|---|---|---|---|---|---|---|
| | | Whole | | | | | | |
| | Light | | Nitrogen/ | | | | | |
| | elements | V₁/ | (nitrogen + | Crystallite | Characteristics | | | |
| | excluded | (V₁ + | oxygen) | size | | Specific | | |
| | Composition | V₂) | Atomic | Mode | Bs | resistance | Permeability | |
| Sample No. | Atomic ratio | % | ratio | nm | T | μΩcm | μ′ | tanδ |
| Comparative | Fe₄₄Co₃₁Si₂₅ | 45 | 0.322 | 1.4 | 0.58 | 120000 | 8 | 0.136 |
| Example 10 | | | | | | | | |
| Example 67 | Fe₄₅Co₃₁Si₂₃ | 48 | 0.314 | 1.9 | 0.81 | 17300 | 85 | 0.093 |
| Example 68 | Fe₄₆Co₃₁Si₂₂ | 51 | 0.310 | 2.5 | 0.86 | 9400 | 94 | 0.061 |
| Example 69 | Fe₄₈Co₃₃Si₁₉ | 55 | 0.305 | 3.1 | 0.90 | 3100 | 104 | 0.040 |
| Example 19 | Fe₄₈Co₃₄Si₁₈ | 58 | 0.298 | 3.4 | 0.90 | 1800 | 112 | 0.038 |
| Example 70 | Fe₄₉Co₃₄Si₁₆ | 60 | 0.283 | 3.9 | 0.96 | 1400 | 131 | 0.032 |
| Example 71 | Fe₅₀Co₃₅Si₁₅ | 63 | 0.276 | 4.0 | 1.05 | 1200 | 123 | 0.024 |
| Example 72 | Fe₅₂Co₃₆Si₁₂ | 68 | 0.272 | 5.0 | 1.14 | 1100 | 110 | 0.080 |
| Example 73 | Fe₅₂Co₃₆Si₁₁ | 70 | 0.268 | 5.6 | 1.19 | 1000 | 106 | 0.090 |
| Comparative | Fe₅₄Co₃₇Si₉ | 75 | 0.263 | 6.7 | 1.35 | 550 | 110 | 0.135 |
| Example 11 | | | | | | | | |

TABLE 9

| | Thin film composition | | | | | | | |
|---|---|---|---|---|---|---|---|---|
| | | Whole | | | | | | |
| | Light | | Nitrogen/ | | | | | |
| | elements | V₁/ | (nitrogen + | Crystallite | Characteristics | | | |
| | excluded | (V₁ + | oxygen) | size | | Specific | | |
| | Composition | V₂) | Atomic | Mode | Bs | resistance | Permeability | |
| Sample No. | Atomic ratio | % | ratio | nm | T | μΩcm | μ′ | tanδ |
| Comparative | Fe₄₄Co₃₁Si₂₅ | 45 | 0.419 | 1.1 | 0.53 | 95000 | 6 | 0.156 |
| Example 12 | | | | | | | | |
| Example 74 | Fe₄₆Co₃₁Si₂₂ | 51 | 0.395 | 2.4 | 0.80 | 3500 | 105 | 0.058 |
| Example 21 | Fe₄₈Co₃₄Si₁₈ | 58 | 0.381 | 2.6 | 0.82 | 1800 | 124 | 0.041 |
| Example 75 | Fe₄₉Co₃₄Si₁₆ | 60 | 0.370 | 3.0 | 0.85 | 1500 | 122 | 0.042 |
| Example 76 | Fe₅₀Co₃₅Si₁₅ | 63 | 0.361 | 3.4 | 0.93 | 1300 | 113 | 0.048 |
| Example 77 | Fe₅₂Co₃₆Si₁₁ | 70 | 0.355 | 4.3 | 1.02 | 1100 | 107 | 0.069 |
| Comparative | Fe₅₄Co₃₇Si₉ | 75 | 0.350 | 6.1 | 1.19 | 500 | 101 | 0.172 |
| Example 13 | | | | | | | | |

According to Tables 8 and 9, the smaller the V₁/(V₁+V₂), the smaller the mode of the crystallite sizes based on volume tended to be. Examples 67 to 73, in which the mode of the crystallite sizes of the crystallites based on volume was within the predetermined range, had good characteristics similarly to Example 19. Moreover, Examples 74 to 77, in which the mode of the crystallite sizes of the crystallites based on volume was within the predetermined range, had good characteristics similarly to Example 21.

In contrast, in Comparative Examples 10 and 12, in which the mode of the crystallite sizes based on volume was too small, Bs and permeability were too low, and tan δ was too high. Comparative Examples 11 and 13, in which the mode of the crystallite sizes based on volume was too large, tan δ was too high.

### Experiment 6

Examples 78 to 82 were carried out as in Example 19 except that the target film thickness was changed. The target film thickness of Example 78 was 0.05 μm. The target film thickness of Example 79 was 0.50 μm. The target film thickness of Example 80 was 5.0 μm. The target film thickness of Example 81 was 10 μm. The target film thickness of Example 82 was 30 μm. Table 10 shows the results.

TABLE 10

| | Thin film composition | | | | | | | | |
|---|---|---|---|---|---|---|---|---|---|
| | | Whole | | | | | | | |
| | Light | | Nitrogen/ | | | | | | |
| | elements | V₁/ | (nitrogen + | Film | Crystallite | Characteristics | | | |
| | excluded | (V₁ + | oxygen) | thickness | size | | Specific | | |
| | Composition | V₂) | Atomic | Average | Mode | Bs | resistance | Permeability | |
| Sample No. | Atomic ratio | % | ratio | μm | nm | T | μΩcm | μ′ | tanδ |
| Example 78 | Fe₄₈Co₃₄Si₁₈ | 58 | 0.290 | 0.050 | 3.0 | 0.91 | 1800 | 108 | 0.041 |
| Example 79 | Fe₄₈Co₃₄Si₁₈ | 58 | 0.292 | 0.517 | 3.2 | 0.90 | 1800 | 113 | 0.038 |
| Example 19 | Fe₄₈Co₃₄Si₁₈ | 58 | 0.298 | 1.66 | 3.4 | 0.90 | 1800 | 112 | 0.038 |
| Example 80 | Fe₄₈Co₃₄Si₁₈ | 58 | 0.305 | 5.14 | 3.6 | 0.91 | 1800 | 115 | 0.040 |
| Example 81 | Fe₄₈Co₃₄Si₁₈ | 58 | 0.307 | 10.7 | 3.7 | 0.90 | 1800 | 114 | 0.039 |
| Example 82 | Fe₄₈Co₃₄Si₁₈ | 58 | 0.324 | 31.3 | 4.0 | 0.88 | 1700 | 119 | 0.046 |

According to Table 10, Examples 78 to 82, in which the nanogranular magnetic film had a composition within the specific range and the mode of the crystallite sizes of the crystallites was within the predetermined range despite the changes in the film thickness, had characteristics very close to those of Example 19. That is, it is assumed that characteristics of the nanogranular magnetic film with a structure within the specific range have very low dependence on film thickness.

### Experiment 7

Examples 83 to 87 were carried out substantially as in Example 19 except that the substrate on which the film was deposited was changed from that of Example 19. Table 11 shows the results.

TABLE 11

| | | Thin film composition | | | | | | | |
|---|---|---|---|---|---|---|---|---|---|
| | | | Whole | | | | | | |
| | | Light | | Nitrogen/ | | | | | |
| | | elements | V₁/ | (nitrogen + | Crystallite | Characteristics | | | |
| | | excluded | (V₁ + | oxygen) | size | | Specific | | |
| | | Composition | V₂) | Atomic | Mode | Bs | resistance | Permeability | |
| Sample No. | Substrate | Atomic ratio | % | ratio | nm | T | μΩcm | μ′ | tanδ |
| Example 19 | 0.28 mmt silicon | Fe₄₈Co₃₄Si₁₈ | 58 | 0.298 | 3.4 | 0.90 | 1800 | 112 | 0.038 |
| | with oxide film | | | | | | | | |
| Example 83 | 0.62 mmt silicon | Fe₄₈Co₃₄Si₁₈ | 58 | 0.292 | 3.2 | 0.90 | 1800 | 113 | 0.038 |
| | with oxide film | | | | | | | | |
| Example 84 | 0.28 mmt silicon | Fe₄₈Co₃₄Si₁₈ | 58 | 0.290 | 3.0 | 0.91 | 1800 | 108 | 0.041 |
| Example 85 | 0.28 mmt sapphire | Fe₄₈Co₃₄Si₁₈ | 58 | 0.305 | 3.6 | 0.91 | 1800 | 115 | 0.040 |
| Example 86 | 0.50 mmt MgO | Fe₄₈Co₃₄Si₁₈ | 58 | 0.307 | 3.7 | 0.90 | 1800 | 114 | 0.039 |
| Example 87 | 0.50 mmt super | Fe₄₈Co₃₄Si₁₈ | 58 | 0.324 | 4.0 | 0.88 | 1700 | 119 | 0.046 |
| | white glass | | | | | | | | |

According to Table 11, Examples 83 to 87, in which the nanogranular magnetic film had a composition within the specific range and the mode of the crystallite sizes of the crystallites was within the predetermined range despite the changes in the substrate, had characteristics very close to those of Example 19. That is, it is assumed that characteristics of the nanogranular magnetic film with a structure within the specific range have very low dependence on substrate.

In all Examples shown in Tables 1 to 11, it was confirmed that the first phases had a composition represented by a composition formula FeₐCo_{b}X1_{c} (in atomic ratio), where X1 included at least one selected from the group consisting of Ni, B, C, P, V, Cr, Mn, Cu, Zn, Nb, Mo, Ru, Rh, Pd, Ag, Sn, Ta, W, Ir, Pt, and Au, and 0.30≤a≤0.90, 0.10≤b≤0.70, 0.00≤c≤0.110, and a+b+c=1 were satisfied.

### Experiment 8

Table 12 shows Examples and Comparative Examples carried out substantially as in Example 21a except that V₁/(V₁+V₂) was changed from that of Example 21a.

TABLE 12

| | Thin film composition | | | | | | | |
|---|---|---|---|---|---|---|---|---|
| | | Whole | | | | | | |
| | Light | | Nitrogen/ | | | | | |
| | elements | V₁/ | (nitrogen + | Crystallite | Characteristics | | | |
| | excluded | (V₁ + | oxygen) | size | | Specific | | |
| | Composition | V₂) | Atomic | Mode | Bs | resistance | Permeability | |
| Sample No. | Atomic ratio | % | ratio | nm | T | μΩcm | μ′ | tanδ |
| Comparative | Fe₄₄Co₃₁Si₂₅ | 45 | 0.401 | 1.2 | 0.69 | 110000 | 13 | 0.138 |
| Example 14 | | | | | | | | |
| Example 88 | Fe₄₅Co₃₁Si₂₃ | 48 | 0.395 | 1.5 | 0.75 | 15000 | 91 | 0.099 |
| Example 89 | Fe₄₆Co₃₁Si₂₂ | 51 | 0.388 | 2.1 | 0.78 | 9000 | 102 | 0.086 |
| Example 90 | Fe₄₈Co₃₃Si₁₉ | 55 | 0.373 | 2.5 | 0.82 | 3000 | 115 | 0.041 |
| Example 21a | Fe₄₈Co₃₄Si₁₈ | 58 | 0.365 | 2.7 | 0.86 | 1800 | 127 | 0.034 |
| Example 91 | Fe₄₉Co₃₄Si₁₆ | 60 | 0.350 | 2.9 | 0.91 | 1600 | 137 | 0.030 |
| Example 92 | Fe₅₀Co₃₅Si₁₅ | 63 | 0.341 | 3.2 | 0.96 | 1400 | 135 | 0.025 |
| Example 93 | Fe₅₂Co₃₆Si₁₂ | 68 | 0.339 | 3.7 | 1.04 | 1200 | 133 | 0.022 |
| Example 94 | Fe₅₂Co₃₆Si₁₁ | 70 | 0.328 | 3.9 | 1.08 | 1100 | 130 | 0.032 |
| Example 95 | Fe₅₄Co₃₇Si₉ | 75 | 0.325 | 4.5 | 1.17 | 900 | 115 | 0.047 |
| Example 96 | Fe₅₆Co₃₉Si₆ | 80 | 0.319 | 5.1 | 1.27 | 750 | 103 | 0.071 |
| Example 97 | Fe₅₇Co₄₀Si₄ | 85 | 0.312 | 5.5 | 1.38 | 650 | 94 | 0.088 |
| Example 98 | Fe₅₈Co₄₀Si₃ | 90 | 0.309 | 6.0 | 1.50 | 550 | 82 | 0.097 |
| Comparative | Fe₅₈Co₄₀Si₂ | 92 | 0.307 | 6.9 | 1.52 | 300 | 66 | 0.130 |
| Example 15 | | | | | | | | |

According to Table 12, the smaller the V₁/(V₁+V₂), the smaller the mode of the crystallite sizes based on volume tended to be. Examples 88 to 98, in which the mode of the crystallite sizes of the crystallites based on volume was within the predetermined range, had good characteristics similarly to Example 21a.

In contrast, in Comparative Example 14, in which the mode of the crystallite sizes based on volume was too small, Bs and permeability were too low, and tan δ was too high. In Comparative Example 15, in which the mode of the crystallite sizes based on volume was too large, specific resistance and permeability were too low, and tan δ was too high.

In all Examples shown in Tables 1 to 12, it was confirmed that the second phase had a composition represented by a composition formula M_{d}OₑN_{f}X2_{g} (in atomic ratio), where M included at least one selected from the group consisting of Si, Al, Ga, Mg, Zr, Hf, and a rare earth element (e.g., Y and La), X2 included at least one selected from the group consisting of F and S, and 0.20≤d≤0.45, 0.00≤g≤0.05, and d+e+f+g=1 were satisfied.

In all Examples shown in Tables 1 to 12, it was confirmed that nitrogen/(oxygen+nitrogen) of the nanogranular magnetic film as a whole was substantially equivalent to f/(e+f) of the second phase.

### REFERENCE NUMERALS

1 . . . nanogranular magnetic film
11 . . . first phase
12 . . . second phase
111 . . . rotation member
111a . . . rotation plate
111b . . . rotation axis
113 . . . substrate
121 . . . cathode
123 . . . sputtering target
131 . . . shutter

1. A nanogranular magnetic film having a structure comprising:
a second phase; and
first phases dispersed in the second phase,
wherein
the first phases comprise nanoscale metal phases comprising Fe and Co,
the second phase comprises oxygen and nitrogen,
the metal phases comprise one or more crystallites, and
the one or more crystallites have crystallite sizes with a mode of 1.5 nm or more and 6.0 nm or less based on volume.

2. The nanogranular magnetic film according to claim 1, wherein the one or more crystallites have crystallite sizes with a mode of 2.0 nm or more and 5.0 nm or less.

3. The nanogranular magnetic film according to claim 1, wherein a value given by dividing a nitrogen concentration of the nanogranular magnetic film by a total of an oxygen concentration and the nitrogen concentration of the nanogranular magnetic film is 0.090 or more and 0.50 or less based on number of atoms.

4. The nanogranular magnetic film according to claim 1, wherein the first phases occupy a volume fraction of 48% or more and 90% or less in total.

5. The nanogranular magnetic film according to claim 1, wherein the first phases occupy a volume fraction of 48% or more and 70% or less in total.

6. A magnetic core comprising the nanogranular magnetic film according to claim 1.

7. An electronic component comprising the nanogranular magnetic film according to claim 1.
